(19) United States
(12) Patent Application Publication
(10) Pub. No.: US 2015/0288907 A1
(43) Pub. Date: Oct. 8, 2015

(54) METHOD AND SYSTEM FOR MANAGING DEFECTS IN FOCAL PLANE ARRAYS USING REDUNDANT COMPONENTS

(71) Applicant: RAYTHEON COMPANY, Waltahm, MA (US)

(72) Inventors: John L. Vampola, Santa Barbara, CA (US); Micky R. Harris, Lompoc, CA (US); Bryan W. Kean, Fairfax, VA (US); Steven E. Botts, Santa Barbara, CA (US)

(73) Assignee: RAYTHEON COMPANY, Waltham, MA (US)

(21) Appl. No.: 14/244,032

(22) Filed: Apr. 3, 2014

(51) Int. Cl. H04N 5/3745; H04N 5/376; H01L 27/146

(52) U.S. Cl. CPC H04N 5/3745; H01L 27/14643; H04N 5/3765

(57) ABSTRACT

A focal plane array having: an imaging array section, comprising: an array of electromagnetic radiation detectors; and an address section providing outputs from selectively enabled detectors. The imaging array section comprises a plurality of circuit blocks, each one of the circuit blocks having a primary circuit and a redundant circuit. Test circuitry is for provided for supplying test signals to test each one of the primary circuits and determining whether a response from the test signals is proper or improper and for storing in the test circuitry in response to such determining select signals associated with each one of the tested circuit blocks. An array controller is provided for, during a subsequent normal operating mode, providing timing pulses to the address section wherein the address section selectively enables the detectors using either the primary or redundant circuits in the plurality of circuit blocks selectively in accordance with the stored select signals.

### TECHNICAL FIELD

This disclosure relates generally to focal plane arrays and more particularly the focal plane arrays having redundant components.

### BACKGROUND

As is known in the art, an image sensor may comprise an array of electromagnetic radiation detectors (sometimes referred to as a focal plane array) for imaging visible or infrared (IR) energy focused onto the image sensor. Each detector (corresponding to a cell image pixel) may include a photodiode or phototransistor which generates charge in proportion to the intensity of light or IR energy incident on the detector. The charge generated by the detector is stored in a charge well, e.g., on a capacitor.

As is also known in the art, the array of detectors is typically formed on a semiconductor wafer. Formed on a different wafer is a read out integrated circuit (ROIC). Such a ROIC may include clocks that synchronize and control the readout of the stored packets of charge from the charge wells, and amplifiers that converts each packet of charge to a voltage. Analog-to-digital converters (ADCs) further convert the analog value of each voltage into a corresponding digital value. Thus the ROIC converts that charge stored in the wells (i.e., analog signals) into corresponding digital signals, for example, in an image sensor.

As is also known in the art, there is a requirement for relatively large focal plane arrays (sensor chip assemblies, SCAs), that can be several inches on a side. The ROIC is very difficult to fabricate with high yields due to inherent defects in the integrated circuit manufacturing process. These defects often occur in areas of the ROIC which, prevents critical circuits from operating, or may cause massive power supply short circuits on the chip. Typical yields can be on the order of <1% to ˜10% for very large ROICs. Since the ROICs are very large, few (perhaps only one) chips are printed on a single very expensive wafer.

More particularly, large sensor chip assemblies are difficult to manufacture due to inherent process defects which have a high probability of impacting a large printed die. Additionally, the processing and handling of large integrated circuits and sensor chip assemblies significantly increases the risk of damage due to their size. Yield loss for small sensors is normally not such an issue since many die are printed on a single wafer; while there may be only a single extremely large die printed per wafer for large sensors. This reduces the available population of available parts, and significantly increases the cost.

As is also known in the art, systems have built with large sensor chips that include some redundant circuitry (such as analog to digital convertors) to help reduce yield losses in very large die.

### SUMMARY

In accordance with the present disclosure, a focal plane array is provided having: an imaging array section, comprising: an array of electromagnetic radiation detectors; and an address section providing outputs from selectively enabled detectors. The imaging array section comprises a plurality of circuit blocks, each one of the circuit blocks having a primary circuit and a redundant circuit. Test circuitry is for provided for supplying test signals to test each one of the primary circuits and determining whether a response from the test signals is proper or improper and for storing in the test circuitry in response to such determining select signals associated with each one of the tested circuit blocks. An array controller is provided for, during a subsequent normal operating mode, providing timing pulses to the address section wherein the address section selectively enables the detectors using either the primary or redundant circuits in the plurality of circuit blocks selectively in accordance with the stored select signals.

In one embodiment, the circuit blocks include, for example: a timing bus block for transmitting the timing signals to the address section; an address decoder circuit block for generating row address enable signals for enabling rows of the detectors selectively from the transmitted timing signals; column buss blocks for transmitting signals from columns of the row enabled detectors selectively from the transmitted timing signals; column amplifier blocks for amplifying and buffering the signals transmitted on the column buss blocks; analog to digital converter (ADC) blocks for converting the amplified and buffered signals into corresponding digital signals; and bias voltage buss blocks for supplying bias voltages to the detectors.

With such an arrangement, a focal plane array chip is provided with read out integrated circuitry having a relatively small initialization logic circuit that, upon wakeup or power up of the chip, tests and validates subsections (the blocks) of the rest of the read out integrated circuitry for proper operation. If a block within the read out integrated circuitry is determined to be operating outside of certain limits, such as power or current, that circuit remains off, and, if available, a substitute, or redundant, circuit is electrically inserted. If a substitute circuit is not available, that section of the read out integrated circuitry remains off so that it cannot prevent the rest of the read out integrated circuitry on the chip from operating normally. This process can be done through logic circuitry on the chip, or from external stimulation. Circuits which are tested can be global circuitry, circuitry common to a subset of the integrated circuit, or circuitry common to individual rows or columns. In the extreme, this can be extended to the pixel unit detector cell circuitry. To ensure that a defect in the wake-up block does not prevent proper power-up, a second backup block can be included on the integrated circuit.

This technology almost ensures that every large sensor readout integrated circuit (ROIC) formed on the chip will yield with high operability because of: 1) The ability to turn on any ROIC to assess performance; 2) The ability to fix defective areas of a ROIC or sensor chip assembly whether caused by inherent process defects or damage inflicted during processing and handling at higher levels of assembly; and 3) The inclusion of large amounts of redundant circuitry and the ability to control the use of primary and redundant circuits either automatically or through external programming.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a diagram showing the relationship between FIGS. 1A and 1B where FIGS. 1A and 1B is an overall block diagram of the focal plane array according to the disclosure;

FIG. 1C is a side elevation view of a focal plane array structure according to the disclosure;

FIG. 2 is a diagram showing the relationship between FIGS. 2A. 2B, 2C and 2D, where FIGS. 2A-2D is a more detailed block diagram of the focal plane array of FIG. 1;

FIG. 3 is a diagram of an exemplary one of a plurality of imaging core arrays used in the focal plane array of FIG. 2;

FIG. 4 is an exemplary one of a plurality of Column Output Section used in the focal plane array of FIG. 2;

FIG. 5 is a diagram showing the relationship between FIGS. 5A and 5B, where FIGS. 5A and 5B is diagram of a test module section used in the focal plane array of FIG. 2;

FIG. 6 is a diagram of an Address Decoder Section used in the focal plane array of FIG. 2;

FIG. 7 is a diagram of a primary/redundant select signal register used in the focal plane array of FIG. 2; and

FIG. 8 is diagram showing the relation chip between FIGS. 8A and 8B, where FIGS. 8A and 8B together is a flow chart of a process used by the focal plane array of FIG. 1.

Like reference symbols in the various drawings indicate like elements.

### DETAILED DESCRIPTION

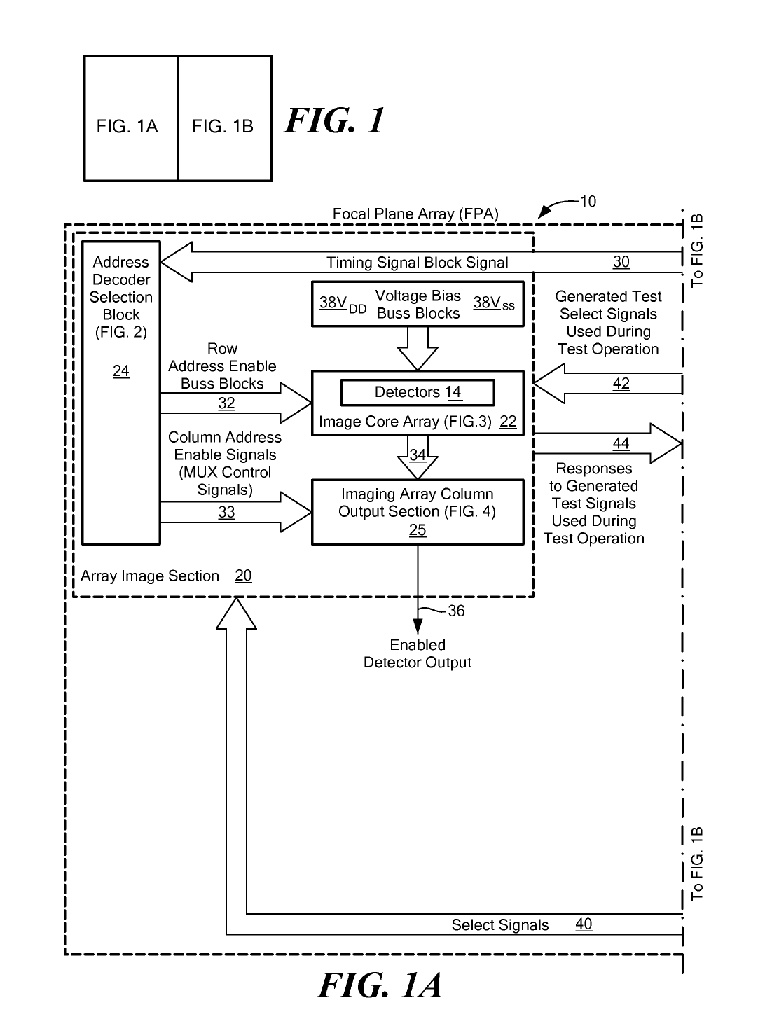

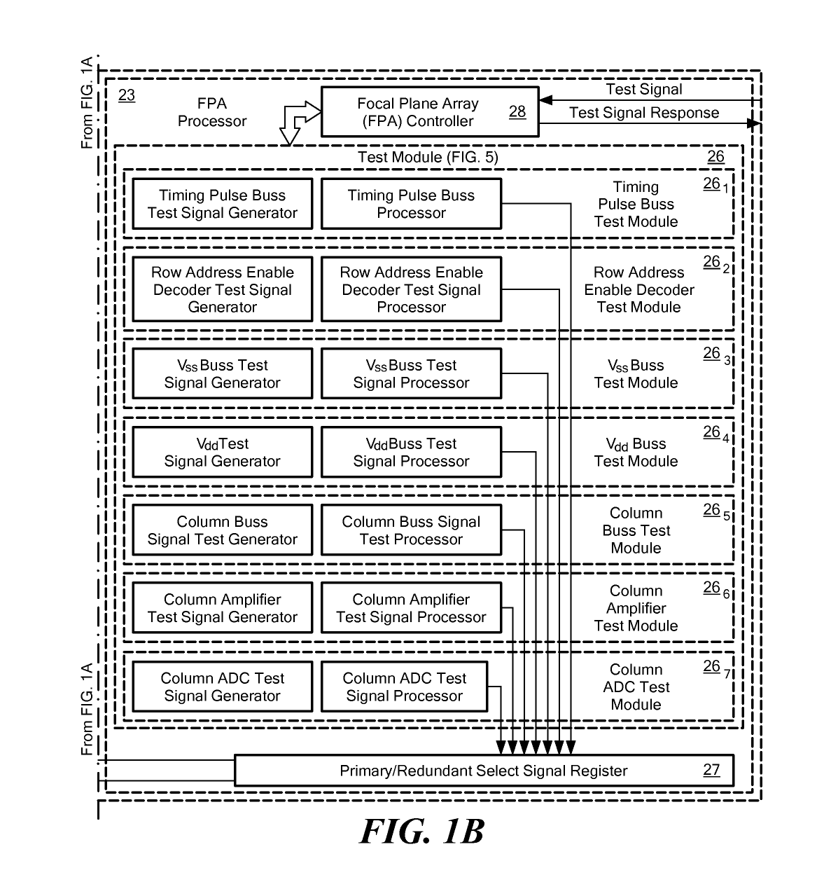

Referring now to FIGS. 1, 1A, 1B and 1C a focal plane array 10 is shown. As shown in FIG. 1C, the focal plane array 10 has an N×N array of radiation detectors 14 on a semiconductor (here for example, HgCdTe) chip 12 bonded and electrically connected to a semiconductor (here for example, silicon) Read Out Integrated Circuit (ROIC) chip 18 through electrical contacts 16, in a stacked arrangement, as shown in FIG. 1C, here using, for example, conventional means for hybridization.

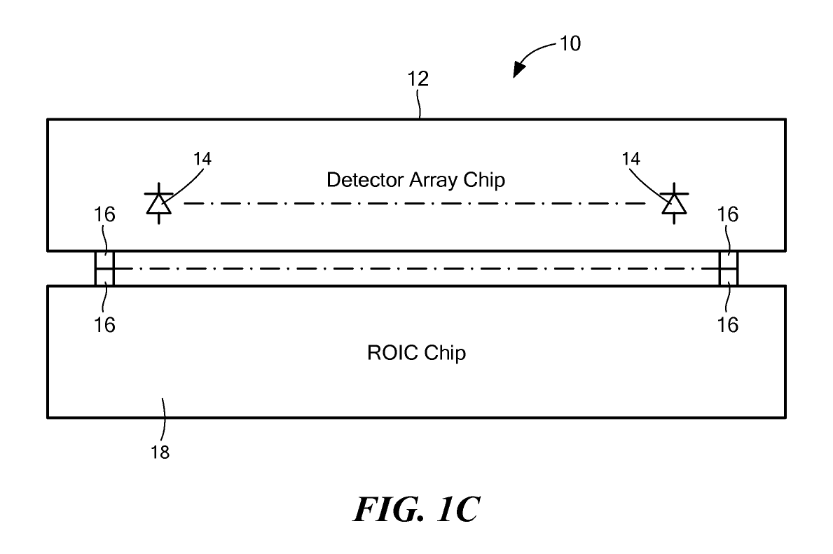

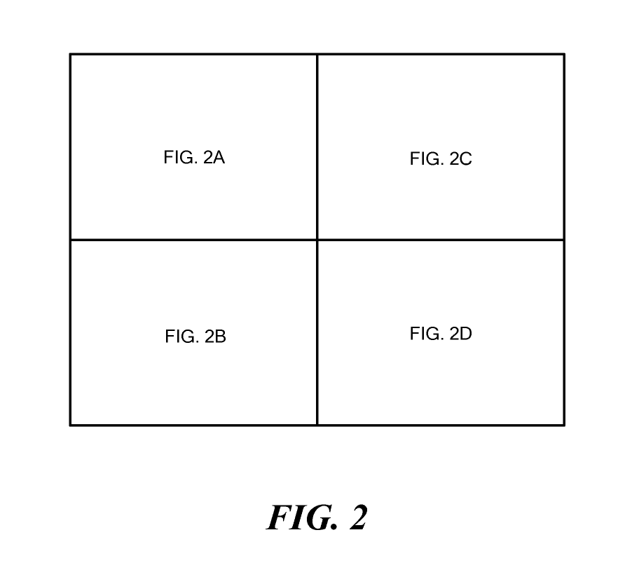

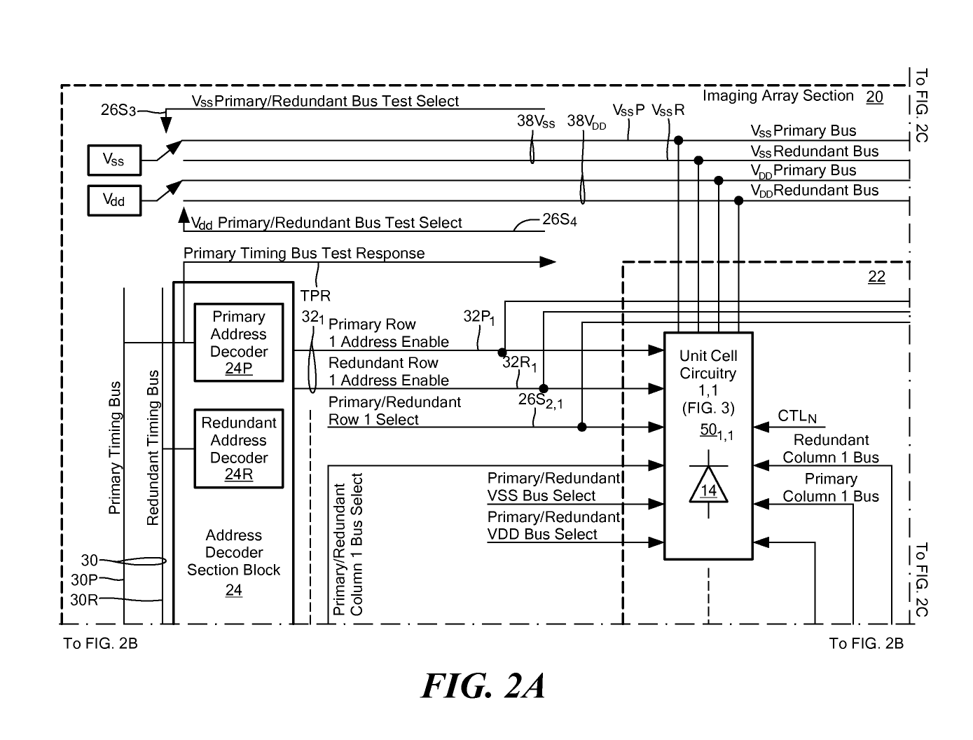

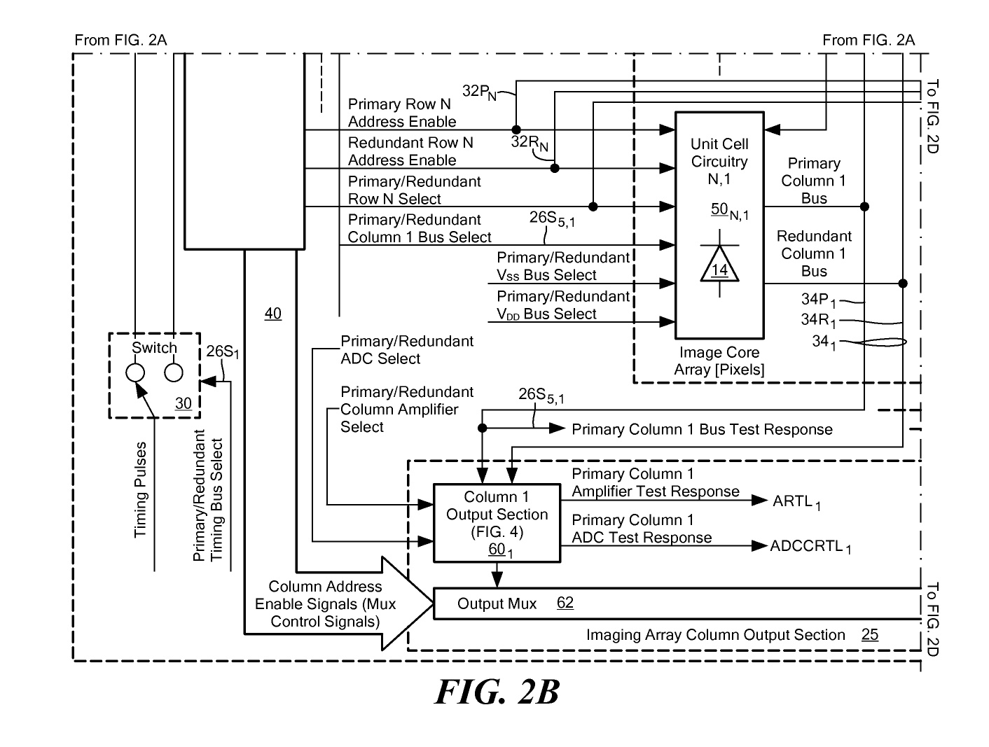

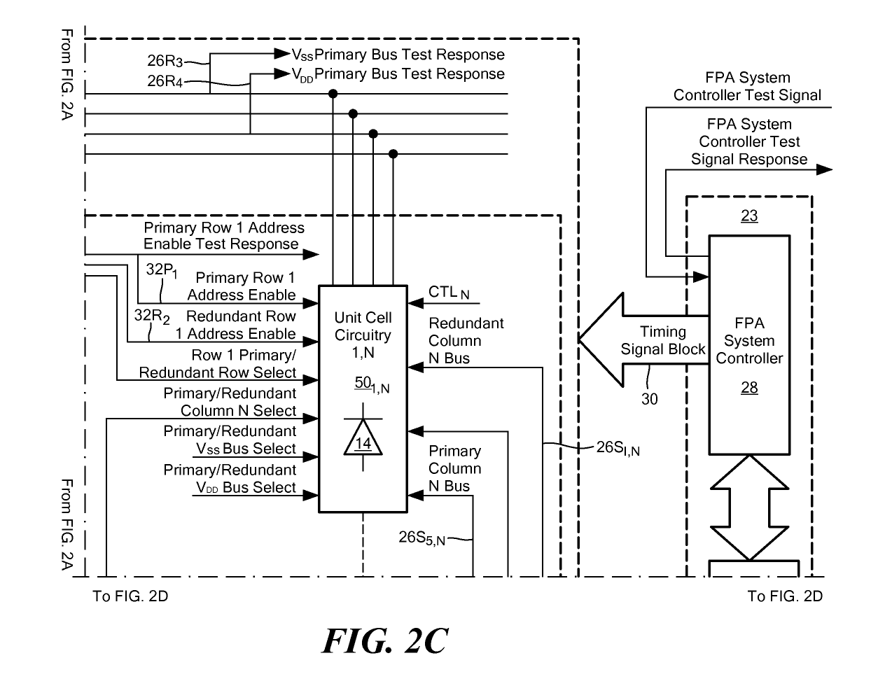

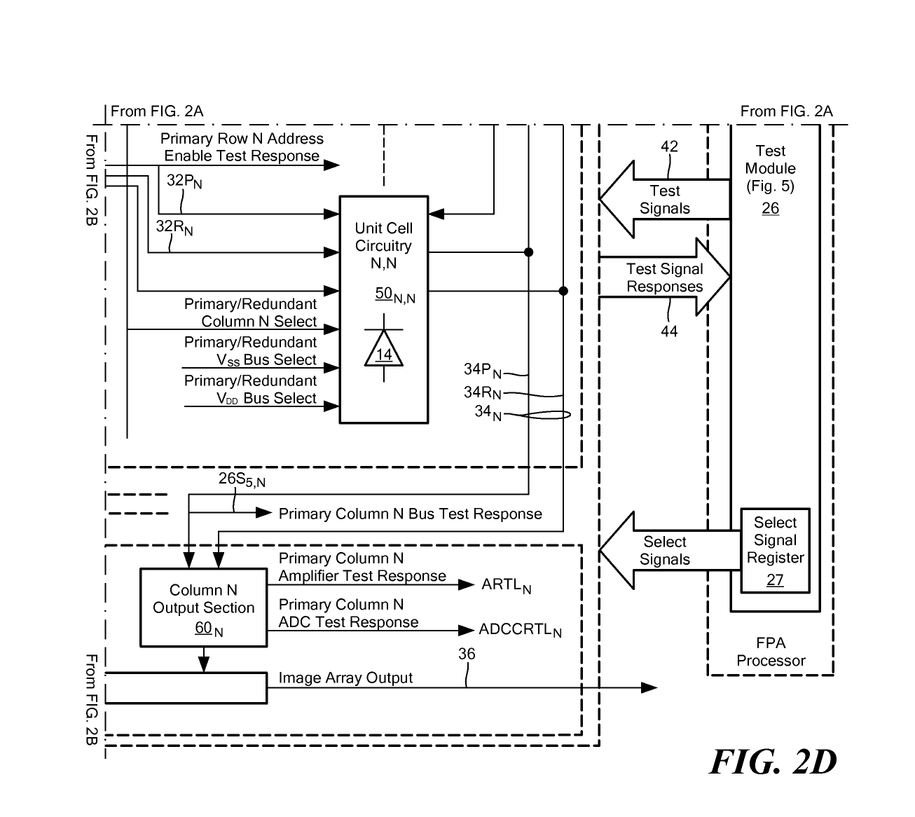

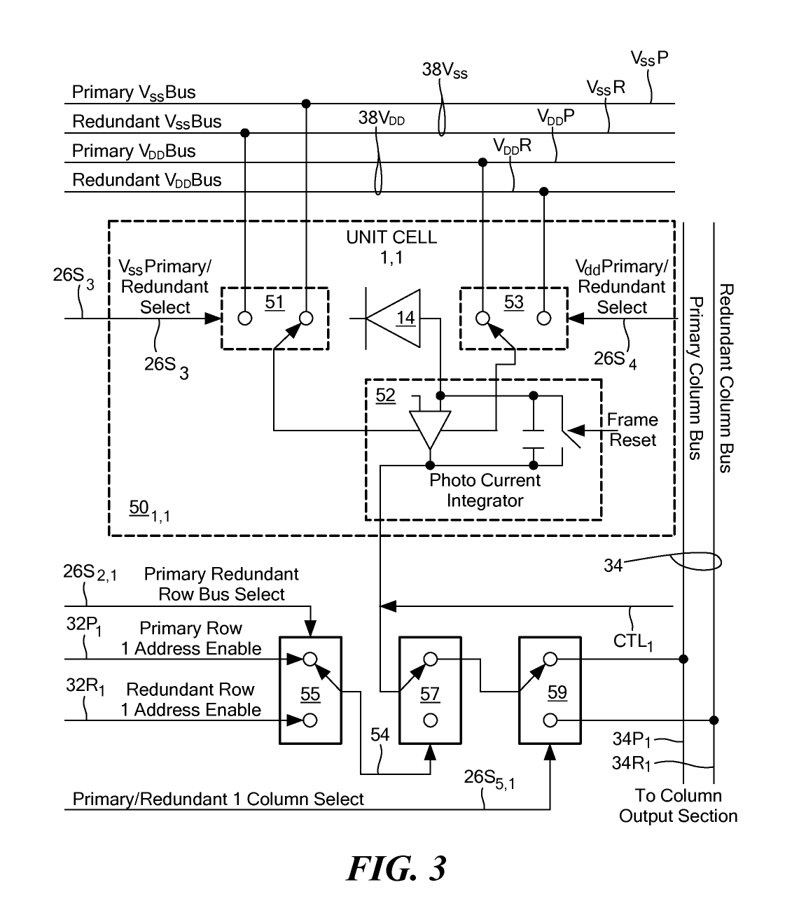

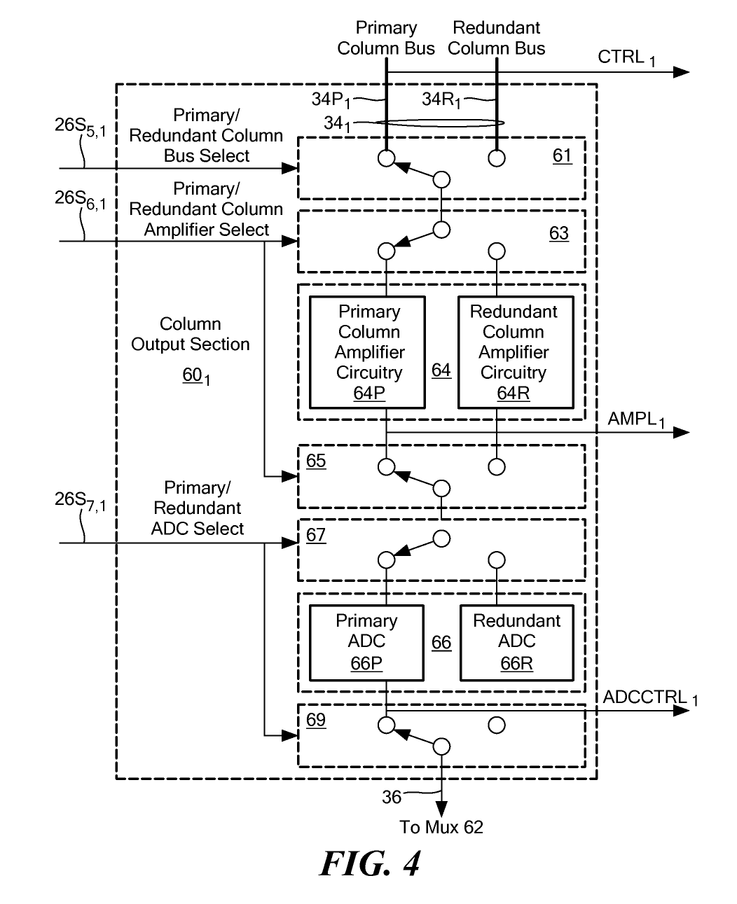

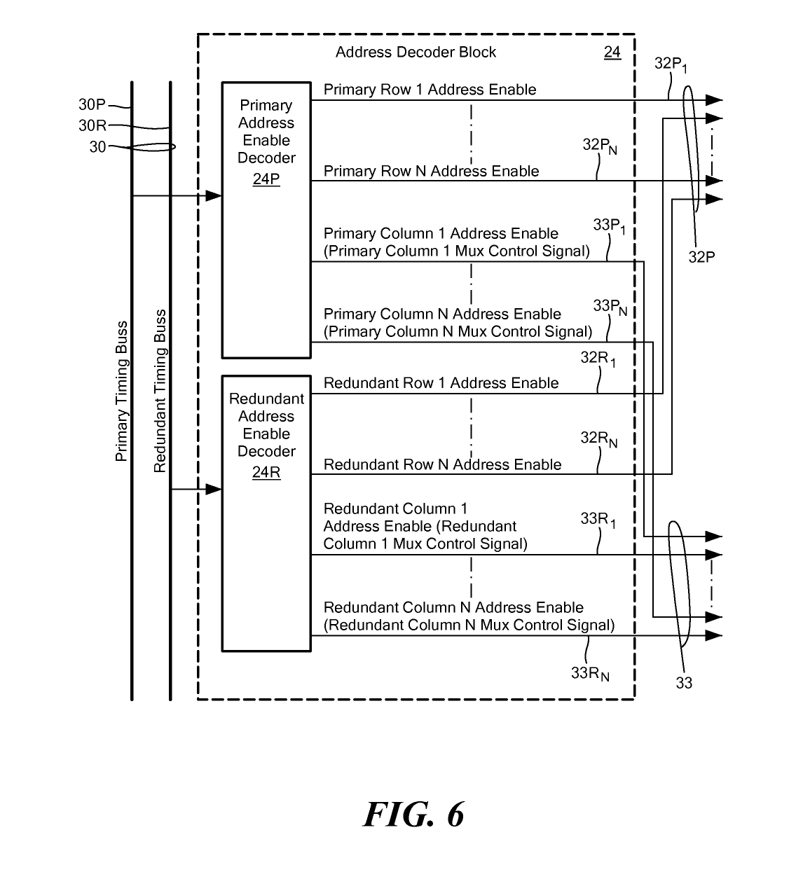

A block diagram of the Focal Plane Array (FPA) 10 is shown in FIG. 1A to include: an array imaging section 20; and a Focal Plane Array (FPA) processor 23. The FPA Processor 23 includes: a test module 26; a primary/redundant select register 27; and a FPA controller 28, interconnected as shown. It should be noted that the Read Out Integrated Circuit (ROIC) formed on chip 18 (FIG. 1C) includes all of the elements in FIG. 1A except for the array of detectors 14 (FIG. 1C) themselves. More particularly, the array imaging section 20 includes: an image core array 22 (to be described in more detail in connection with FIG. 3) having therein the array of radiation detectors 14 on the semiconductor chip 12 (FIG. 1C); an Address Decoder Section Block 24 (to be described in more detail in connection with FIGS. 2 and 6; and an Imaging Array Column Output Section 25 (to be described in more detail in connection with FIG. 4). As will be described in more detail in connection with FIG. 2, the detectors 14 are arranged in a matrix of N rows and N columns. The Address Decoder Section Block 24 provides row enable signals and column address multiplexer control signals to couple outputs from selected ones of the radiation detectors 14 in the image core array 22 to pass to output 36 through an Imaging Array Column Output Section 25 (to be described in more detail in connection with FIG. 4).

While, the array imaging section 20 will be described in more detail below, it should be noted that the imaging array section 20 includes a plurality of circuit blocks, each one of the circuit blocks having a primary circuit and a redundant circuit. The circuit blocks will be described in more detail below; suffice it to say here that the circuit blocks include, for example:
(1) a Timing Signal Block 30 (having a primary timing signal buss 30P and a redundant timing signal buss 30R, to be described in connection with FIG. 2;
(2) the Address Decoder Section Block 24 having a primary address decoder 241 and a redundant address decoder 24R (FIG. 2 and FIG. 6);
(3) a Row Address Enable Block 32 (FIG. 1) having N row address enable buss blocks 32₁-32_{N} (FIG. 2). Each one of the N row address enable buss blocks 32₁-32_{N} has a corresponding one of N primary row address enable busses 32P₁-32P_{N}, respectively, as indicted in FIG. 2, and a corresponding one of N redundant row address enable busses 32R₁-32R_{N}, respectively, as indicated in FIG. 2; each one of the N primary row enable busses 32P₁ through 32P_{N} being coupled to the unit cell circuitry in a corresponding one of the N rows of unit cell circuitry 50_{1,1}-50_{1,N} through 50_{N,1}-50_{N,N}, respectively, as indicated in FIG. 2; and, each one of the N redundant row enable busses 32R₁ through 32R_{N} being coupled to the unit cell circuitry in a corresponding one of the N rows of unit cell circuitry 50_{1,1}-50_{1,N} through 50_{N,1}-50_{N,N}, respectively, as indicated in FIG. 2.
(4) a Column Buss Section 34 (FIG. 1) having N column buss blocks 34₁-34_{N} (FIG. 2). Each one of the N column buss blocks 34₁-34_{N} has a corresponding one of N primary column busses 34P₁-34P_{N}, respectively, as indicted in FIG. 2, and a corresponding one of N redundant column busses 34R₁-34R_{N}, respectively, as indicated in FIG. 2; each one of the N primary column busses 34P₁ through 34P_{N} being coupled to the unit cell circuitry in a corresponding one of the N columns of unit cell circuitry 50_{1,1}-50_{N,1} through 50_{1,N}-50_{N,N}, respectively, as indicated in FIG. 2; and, each one of the N redundant column busses 34R₁ through 34R_{N} being coupled to the unit cell circuitry in a corresponding one of the N columns of unit cell circuitry 50_{1,1}-50_{N,1} through 50_{1,N}-50_{N,N}, respectively, as indicated in FIG. 2.
(5) Imaging Array Column Output Section 25 (FIGS. 1 and 2) having N column output sections 60₁-60_{N}, an exemplary one thereof, here section 60 being shown in FIG. 4)
   (A) N column output sections 60₁-60_{N}; (FIG. 2), each one of the N column sections 60₁-60_{N} being coupled to a corresponding one of the N column buss blocks 34₁-34_{N} (FIG. 2). Each one of the N column output sections 60₁-60_{N}; is identical in construction. An exemplary one thereof, here for example, column output section 60₁ is shown in more detail in FIG. 4 to include:
      (i) an Amplifier Block 64 (FIG. 4) having a primary column amplifier 64P and a redundant amplifier 64R; a selected one thereof being selectively connected to one of the primary column buss 34P₁ or redundant column buss 34R₁ through a pair of serially connected switches 61 and 63, as shown; and
      (ii) an Analog to Digital (ADC) Block 66 (FIG. 4) having a primary ADC 66P and a redundant ADC 66R, a selected one thereof being selectively connected to one of the primary column amplifiers 64P or redundant column amplifiers 64R through a pair of serially connected switches 65 and 67, as shown; and
   (B) an output multiplexer (MUX) 62 (FIG. 2) selectively coupled to the primary ADC 66P or redundant ADC 66R, through a switch 69 (FIG. 4);
(6) a V_{dd} Bias Voltage Buss Block 38V_{dd} (FIG. 2) having a primary V_{dd} bias V_{dd}P buss and a redundant Vdd buss V_{dd}R for providing a bias voltages to the image core array 22 (FIG. 2); and
(7) a Vₛₛ Bias Voltage Buss Block 38Vₛₛ (FIG. 2) having a primary Vₛₛ bias VₛₛP buss and a redundant Vₛₛ buss VₛₛR a redundant Vₛₛ buss) for providing a bias voltages to the image core array 22 (FIG. 2).

Referring again to FIG. 1, the focal plane array (FPA) processor 23 with the FPA controller 28 and test circuitry module 26, provides, during a test mode, test signals on select lines 42 to sequentially test each one of the primary circuits of the circuit blocks described above and determining whether a response from the test signal on lines 44 provided to the tested primary circuit on lines 44 is proper or improper (e.g. the latter being a fault) and for storing in the Primary/Redundant Select Signal Register 27 of the FPA processor 23 a select signal associated with each one of the tested circuit blocks. The data stored in the Primary/Redundant Select Signal Register 27 controls which of the primary or redundant circuits in each one of the plurality of circuit blocks is used.

The FPA processor 23 during a subsequent normal operating mode provides the timing pulses on the Timing Signal Block 30, FIG. 2 to the Address Decoder Section Block 24. The Address Decoder Block 24 selectively enables the rows of detectors 14 using either the primary or redundant circuits in each one of the plurality of circuit blocks via buss 32 selectively in accordance with the stored select signal associated with such one of the circuit blocks.

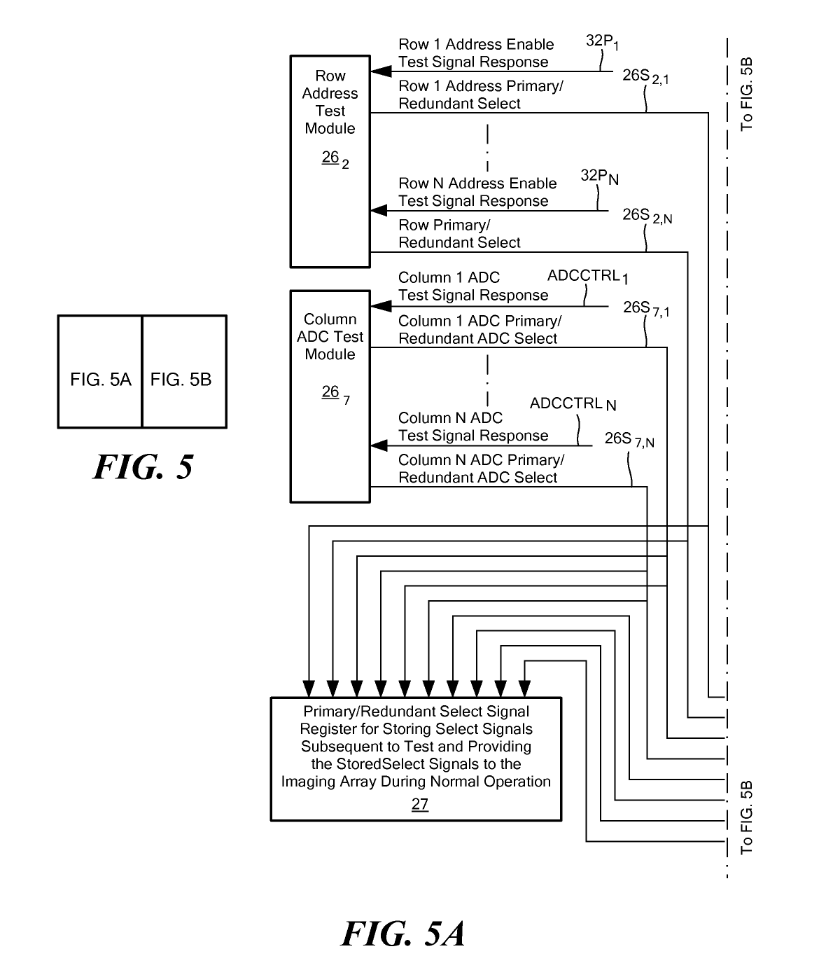

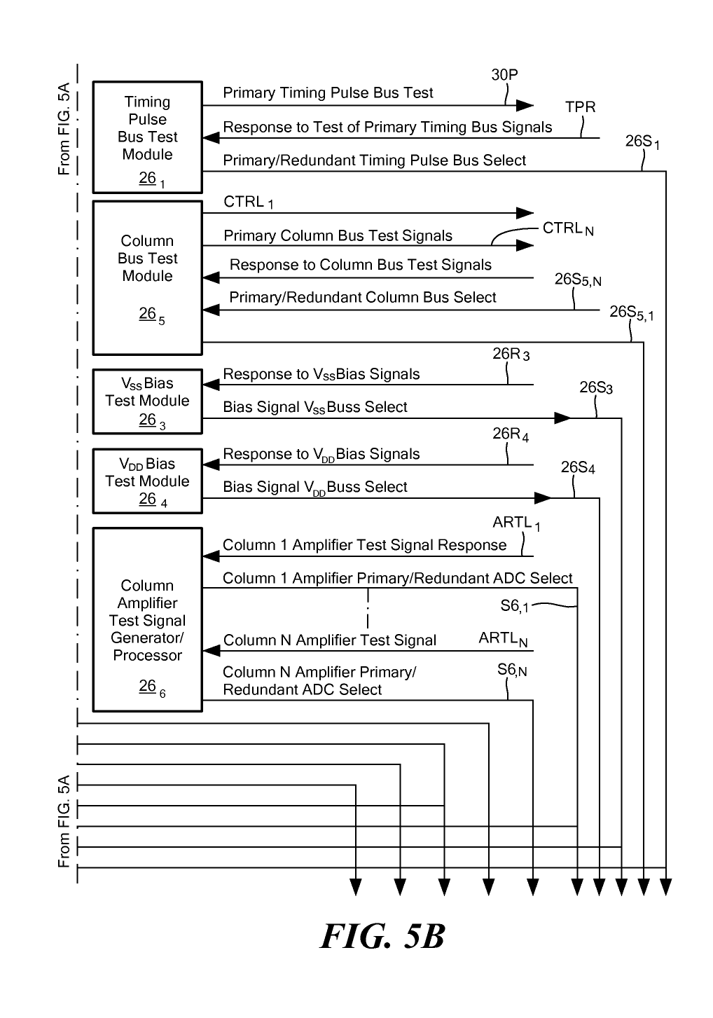

Thus, the test module 26 (FIGS. 2 and 5) includes;
a timing pulse buss test signal module 26₁ for transmitting a predetermined sequence of timing pulses to the primary timing signal buss 30P through a switch 30_{SWITCH} (FIG. 2) during the test mode and for monitoring the primary timing pulses received by the primary address decoder 24P via timing pulse test response line TPR (FIGS. 2 and 5). If the monitored pulses match the predetermined sequence and are therefore proper, the timing pulse buss test signal module repeats the predetermined sequence of timing pulses on the primary timing pulse; however, if the monitored sequence does not match the predetermined sequence, the primary/redundant select signal register 27 selects the redundant position of 30_{SWITCH} (it being noted that the register 27 initially selects, at the commencement of the testing, to be described, the primary circuit in the circuit blocks), using a timing pulse block select 26S₁ signal (FIGS. 2 and 5), to couple the timing pulses through the switch 30_{SWITCH} to the redundant timing signal buss 30R and then to the redundant address decoder 24R for subsequent testing to the, to be described, and for a subsequent normal operating mode. It is noted in FIG. SB that the timing pulse block select 26S₁ signal is stored in register 27;
a row address enable decoder test module 26₂ for sequentially receiving enable signals from primary row 1 address buss enable 32P₁ through primary row N buss enable 32P_{N} in response to timing pulses transmitted on the primary timing pulse buss. It is noted that each one of the enable signals from primary row 1 address buss enable 32P₁ through primary row N buss enable 32P_{N} is, in effect tested independently using either the primary timing buss 30P if it responded properly as described above, or to timing pulses transmitted on the redundant turning pulse buss 30R, if the primary timing buss 30P did not respond properly as described above. If the tested one of the primary row 1 address buss enable 32P₁ through primary row N buss enable 32P_{N} responds properly, such properly operating buss enable is used during the subsequent normal operating mode; however if the tested one of the enables is not operating properly the associated redundant enable is selected for the subsequent normal operating mode. Thus, the row address test module 26₂ produces at the end of the test, a row address select signal 26S_{2,1}-26S_{2,N} for each one of the row 1 address buss enable 32P₁ through primary row N buss enable 32P_{N}, respectively, in response to timing pulse block select 26S₁ signal. The row address select signal 26_{2,1}-26_{2,N} are stored in register 27 and are used to select the properly operating row enables for enabling the rows of detectors 14;
a Vₛₛ buss test signal module 26₃ for, in response to the register 27 selectively coupling the primary Vₛₛ bus VₛₛP to a Vₛₛ supply (FIG. 2), for monitoring the voltage actually produced on the primary Vₛₛ bus via line 26R₃ to determine whether the primary Vₛₛ bus VₛₛP produces a Vₛₛ voltage within a predetermined acceptable range of voltages. If the primary Vₛₛ bus VₛₛP responds properly, the Vₛₛ supply remains connected to the V_{ssP} supply; if on the other hand, the primary Vₛₛ bus VₛₛP does not respond properly, the redundant Vₛₛ bus VₛₛR is coupled to the Vₛₛ supply in response to a Vₛₛ select signal 26S₃ produced by the Vₛₛ buss test signal module 26₃. The Vₛₛ select signal 26S₃ is stored in register 27.
a V_{dd} buss test signal module 26₄ for, in response to the register 27 selectively coupling the primary V_{dd} bus V_{dd}P to a V_{dd} supply (FIG. 2), for monitoring the voltage actually produced on the primary V_{dd} bus V_{dd}P via line 26R₄ to determine whether the V_{dd} bus V_{dd}P produces a V_{dd} voltage within a predetermined acceptable range of voltages, if the primary V_{dd} bus V_{dd}P responds properly, the V_{dd} supply remains connected to the V_{ddP} supply; if on the other hand, the primary V_{dd} bus V_{dd}P does not respond properly, the redundant V_{dd} bus V_{dd}R is coupled to the V_{dd} supply in response to a V_{dd} select signal 26S₄ produced by the V_{dd} buss test signal module 26₄. The V_{dd} select signal 26S₄ is stored in register 27;
a column buss test module 26₅ for, transmitting test signals to each one of the N primary column busses 34P₁-34P_{N} through the columns of unit cell circuitry 50_{1,1}-50_{N,1} through 50_{1,N}-50_{N,N} via column test lines CTL₁-CTL_{N}, respectively (as shown in FIG. 2 and in FIG. 3 for exemplary unit cell circuitry 50_{1,1}) and for monitoring the signals actually produced on the N primary column busses 34P₁-34P_{N} and fed to the test module via column test response lines CTRL₁-CTRL_{N}, respectively, as indicated to determine whether the response on each one of the N primary column busses 34P₁-34P_{N}, respectively is proper; and if determined improper, the register 27 selects via select signals 26S_{5,1}-26S_{5,N} the redundant buss 34R₁-34R_{N} associated with such improperly responding primary column buss 34P₁-34P_{N} for subsequent testing and for use during normal operating mode. Thus, each of the N columns of unit cell circuitry 50_{1,1}-50_{1,N} is fed a corresponding one of the column test lines CTL₁-CTL_{N}, respectively, as indicated in FIG. 2. The response of each one of the N columns of unit cell circuitry 50_{1,1}-50_{1,N} is monitored via response lines CTRL₁-CTRL_{N}, respectively. If a response is proper, the column buss test module 26₅ produces select signals 26S_{5,1}-26S_{5,N} of the properly responding column buses to leave the primary column busses 34P₁-34P_{N} coupled to the N columns of unit cell circuitry 50_{1,1}-50_{1,N}; however, for the column busses not responding properly, the unit cell circuitry 50_{1,1}-50_{1,N} coupled thereto are switched to the redundant column busses 34R₁-34R_{N}. The select signals 26S_{5,1}-26S_{5,N} are stored in register 27.
a column amplifier test signal module 26₆ for monitoring the response of each of the N primary column amplifiers 64P in block 64 (FIG. 4) via amplifier test response lines ARTL₁-ARTL_{N} (FIG. 2) in response to the signals on the column buss fed thereto (either the primary column 34P₁, for example, if it responded properly to the column test described above, or the associated redundant column buss 34R₁, in this example, if the primary column buss 34P₁ did not respond properly), and if determined improper, the register 27 selects via select signal 26S_{6,1} the associated redundant column amplifier 64R for subsequent testing and for use during normal operating mode. The select signal. 26S_{6,1} is stored in register 27. Each of the N primary column amplifiers 64P is tested independently in like manner resulting in select signals 26S_{6,1}-26S_{6,N} being stored in register 27;
a column ADC test signal module 26₇ monitoring the response of each of the N primary ADCs 66P in Analog to Digital (ADC) Block 66 (FIG. 4) via ADC response test lines ADCRTL₁-ADCRTL₄ respectively, to the signals passing through a corresponding one of the N selected primary or redundant column buss and selected primary or redundant column amplifier fed thereto, and if determined improper, the register 27 selects via select signals 26S_{7,1}-26S_{7,N} the associated redundant ADC 66R for each of the N ADCs, respectively, for any subsequent testing and for use during normal operating mode. Thus, the column ADC test signal module 26₇ operates in like manner to the column amplifier test signal module 26₆ described above. The select signals 26S_{7,1}-26S_{7,N} are stored in register 27.

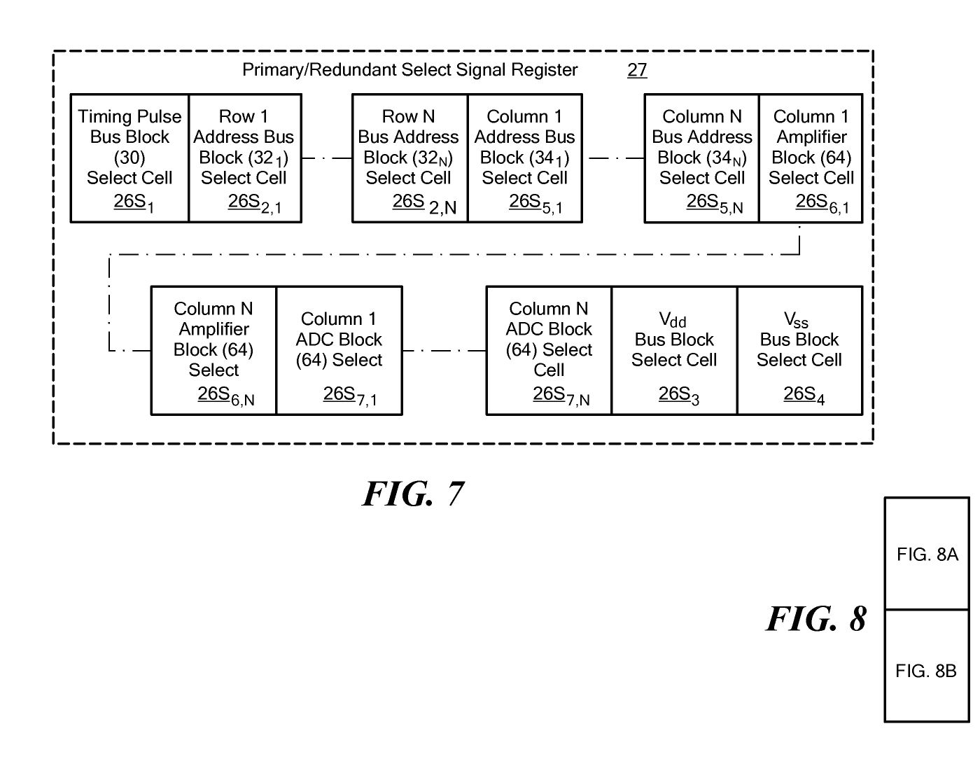

More particularly, the primary/redundant select signal register 27 (FIG. 7) includes a plurality of storage cells, each one of the storage cells corresponding to one of the plurality of circuit blocks. Here, for example, the prima/redundant select signal register 27 stores a logic 1 for the corresponding circuit block if the primary circuit in the block is to be selected and stores a logic 0 if the redundant circuit in the block is to be selected. Initially, prior to the test mode, the FPA controller 28 stores a logic 1 in all of the storage cells thereof resulting in the primary circuit in each of the circuit blocks being selected. The responses of the primary elements are monitored. If a non-operating condition is detected on the primary circuit in a circuit block, the controller 28 changes the logic 1 in the storage cell of the register 27 corresponding to the non-operating circuit block a logic 0.

More particularly, if one or more primary timing signals are not detected as operating properly, then the logic in the corresponding storage cell of register 27 is changed to a logical 0. If one or more row enable responses are not detected, the logic is changed to a logic 0 for those row enables not responding properly, as described above. If one or more column busses are not responding properly as described above, the logic associated with the non-properly responding column buss is changed to a logic 0 for those column buss enables not responding. If one or more column amplifiers are not responding properly as described above, the logic is changed to a logic 0 for those column amplifiers not responding properly. If one or more column ADCs responses are not proper as described above, the logic for the non-properly responding ADC is changed to a logic 0. If the V_{DD} bias buss response is not proper as described above, the logic is changed to a logic 0. If the V_{SS} bias buss response is not proper as described above, the logic is changed to a logic 0. It should be understood that other logic may be used, for example, if tri-state logic (or 2 bits) is used the following would be stored in the two-bit storage cells: a logic 11=Primary circuit select; a logic 00 for a Redundant circuit select; and a logic 01 or logic 10 for a Disable condition, if such is desired for the implementation.

Referring now again to FIG. 2, the image core array 22 is shown to include an N×N array of N rows and N columns of identical unit cell circuits 50_{1,1}-50_{N,N}. Each one of the unit cell circuits 50_{1,1}-50_{N,N} is identical in construction and is shown in more detail in FIG. 3; it is noted that each one of the circuits 50_{1,1}-50_{N,N} includes a corresponding one of the N×N detectors 14. Each one of the N rows ofunit cell circuits 50_{1,1}-50_{N,N} is coupled to either: a corresponding one of N primary row address enable lines (primary row 1 address enable-primary row N address enable, respectively); or to a corresponding one of N redundant row address lines (redundant enable row 1 address enable redundant row N address enable, respectively), selectively in accordance with the select signals 268_{2,1}-26_{2,N} stored in register 27, as described above Each one of the columns of unit cell circuits 50_{1,1}-50_{N,N} is coupled to either: a corresponding one of N primary column buss lines (primary column 1 buss through primary column N buss, respectively); or to a corresponding one of N redundant column buss lines (redundant column 1 buss through redundant column N buss, respectively), selectively in accordance with the select signal 26S_{5,1}-26S_{5,N} stored in register 27, as described above.

An exemplary one of the unit cell circuits 50_{1,1}-50_{N,N}, here unit cell circuit 50_{1,1} is shown in detail in FIG. 3 to include: a corresponding one of the N×N array of detectors 14 and a current integrator 52 for integrating charge produced by the detector 14. The integrator 52 is periodically reset by timing signals produced by the focal plane array system controller 28 in a conventional manner during normal operation of the array 10. Bias voltages, here Vₛₛ and V_{dd} are provided by voltages on either a primary bias Vₛₛ buss or a redundant Vₛₛ bias buss and on either a primary V_{dd} bias buss or a redundant V_{dd} bias buss; the primary or redundant busses being selected through switches 51, 53, respectively, in response to select signals 26S₃ and 26S₄ respectively, produced in response to the test signals during the test mode and stored in register 27 (FIG. 1), as described above. The output on the integrator 52 is fed to either a primary column 1 buss 34P₁ or a redundant column 1 buss 34R₁ selected via switch 57 (FIG. 3) in response to select signal 26S_{5,1} produced in response to the test signals, as described above. The integrator 52 is reset after each frame of data by a FRAME RESET signal supplied by the FM system controller 28. More particularly, if, during the test mode, it was determined that the primary row 1 address enable is operating properly, the primary/redundant row buss select signal 26S_{2,1} stored in register 27 operates switch 55 (FIG. 3) to select the primary row buss 32P₁ as the row address buss for the unit cell 50_{1,1}. On the other hand, if during the test mode, it was determined that the primary row 1 address enable 32P₁ is not operating properly, the primary/redundant row 1 address buss select signal 26S_{2,1} stored in register 27 operates switch 55 to select the redundant row 1 address buss 32R₁ as the row address buss for the unit cell 50_{1,1}. In either case, a select signal 54 is fed to switch 57; however, if row 1 is not enabled, neither the primary row enable 32P₁ nor the redundant row enable 32R₁ will be enabled in which case a select signal will not be fed to switch 57. The output of integrator 52 is fed to one terminal of a switch 57 (FIG. 3); the other terminal to the switch 57 being open. If either switch 57 is enabled by the select signal 54, the unit cells in row 1 are selected and the output of the integrator 52 is fed to either an input of switch 57 connected to the primary column 1 buss 34P₁ or to the redundant column 1 buss 34R₁, through switch 59 selectively in accordance with the primary/redundant column 1 select signal 26_{5,1} stored in register 27 during the test mode depending on whether, during the test mode it was determined whether the primary column 1 buss was operating properly. Thus, if the detectors 14 in row 1 are not selected by the timing signals fed to the Address Decoder Section Block 24 (FIGS. 1 and 2), the outputs of the integrators 52 in the unit cells 50_{1,1}-50_{1,N} are decoupled from both the primary column buss 34P₁ and the redundant column buss 34R₁ because on the non-enabled switch 57. On the other hand, if the detectors 14 in row 1 are selected by the timing signals fed to the Address Decoder Section Block 24, the output of integrator 52 will pass to either the primary column buss 34P₁ or the redundant column buss 34R₁ selectively in accordance with the select signal stored 26_{5,1} in register 27 after the test mode.

Referring now to FIG. 4, as noted above in connection with FIGS. 1 and 2, the primary column busses 34P_{1,N} and redundant column busses 34R_{1,N} are coupled to the Imaging Array Column Output Section 25. More particularly, each one of the N sets of primary column 1 buss and redundant column 1 buss through primary column N buss and redundant column N buss is connected to a corresponding one of N identical column output section 60₁-60_{N} respectively, as shown. An exemplary one thereof column 1 output section 60₁ is shown in detail in FIG. 4. The exemplary output section 60₁ is connected, through switch 61, to either the primary column 1 buss or the redundant column 1 buss selectively in accordance with a primary/redundant column 1 buss select signal stored in register 27 (FIG. 1) during the test mode. The output section 60₁ includes a primary amplifier 64_{P} and redundant amplifier 64R, one thereof being connected, through switch 63, either to the primary and redundant column busses selectively in accordance with a primary/redundant column amplifier select signal stored in the register 27 (FIG. 1) during the test mode. The output section 60₁ also includes a primary ADC, ADC_{P}, and redundant ADC, ADC_{R} one thereof being connected, through switch 65, to, through switch 67, either the primary or redundant amplifiers 64P, 64R selectively and to, through switch 69, an output multiplexer 62 selectively in accordance with a primary/redundant ADC select signal stored in register 27 (FIG. 1) during the test mode.

The N column busses are selected in parallel, and then the detectors in a selected row are read out sequentially through Column 1 Output Section 60₁ through. Column N Output Section 60_{N} via the Output Multiplexer 62 (FIGS. 1 and 2).

If for example, as a result of the initial testing in the set-up mode, the redundant column 1 buss is selected, and as a result of the test, the primary column amplifier 64P in column 1 is selected and the redundant ADC in column 1 is selected and the address row enable decoder selects the detectors 14 in row 1, the packet of charge stored in a charge well of the detector 14_{1,1} is integrated by integrator 52_{1,1} (FIG. 3) and passes through the redundant column 1 bus, then through the primary column 1 amplifier 64P, then is converted into a corresponding digital word by the redundant ADCR connected to the column 1 amplifier and then, the digital word passes through the Imaging Array Column Output Section 25 (FIG. 1) to the output 36.

Referring now to FIG. 6, the Address Decoder Section Block 24 includes: a primary address enable decoder 24P connected to the primary timing buss 30P to producing primary row address enables 32P₁-32P₅ and primary multiplexer control signals 33P₁-33P in response to timing signals on the primary timing buss 30P for the detectors 14 in rows 1 through N and columns 1 through N; and a redundant address enabler decoder 24R connected to the redundant timing buss 30R to producing redundant row address enables 32R₁-32R₅ and redundant multiplexer control signals 33R₁-33R_{N} for rows 1 through N and columns 1 through N for the detectors 14 in rows 1 through N and columns 1 through N.

As noted above, the Read Out Integrated Circuit (ROIC) formed on chip 18 (FIG. 1) includes all of the elements in FIG. 2 except for the array of detectors 14. Thus, the ROIL includes primary and redundant circuits each comprising a plurality of circuit blocks arranged for controlling readout of packets of charge stored wells of the detectors 14 and for converting the readout stored packets into corresponding voltages and/or converting such voltages into corresponding digital signals. The circuit blocks include, for example: the Timing Signal Block 30 (FIGS. 1 and 2) for transmitting the timing signals to the address section; an Address Decoder Section Block 24 for generating row address enable signals for enabling rows of the detectors selectively from the transmitted timing signals; Column Buss Section 34 for transmitting signals from columns of the row enabled detectors selectively from the transmitted timing signals; Amplifier Blocks 64 (FIG. 4) for amplifying and buffering the signals transmitted on the column buss blocks; analog to digital converter (ADC) blocks (FIG. 4) for converting the amplified and buffered signals into corresponding digital signals; and bias voltage buss blocks 28 (FIG. 2) for supplying bias voltages to the detectors 14.

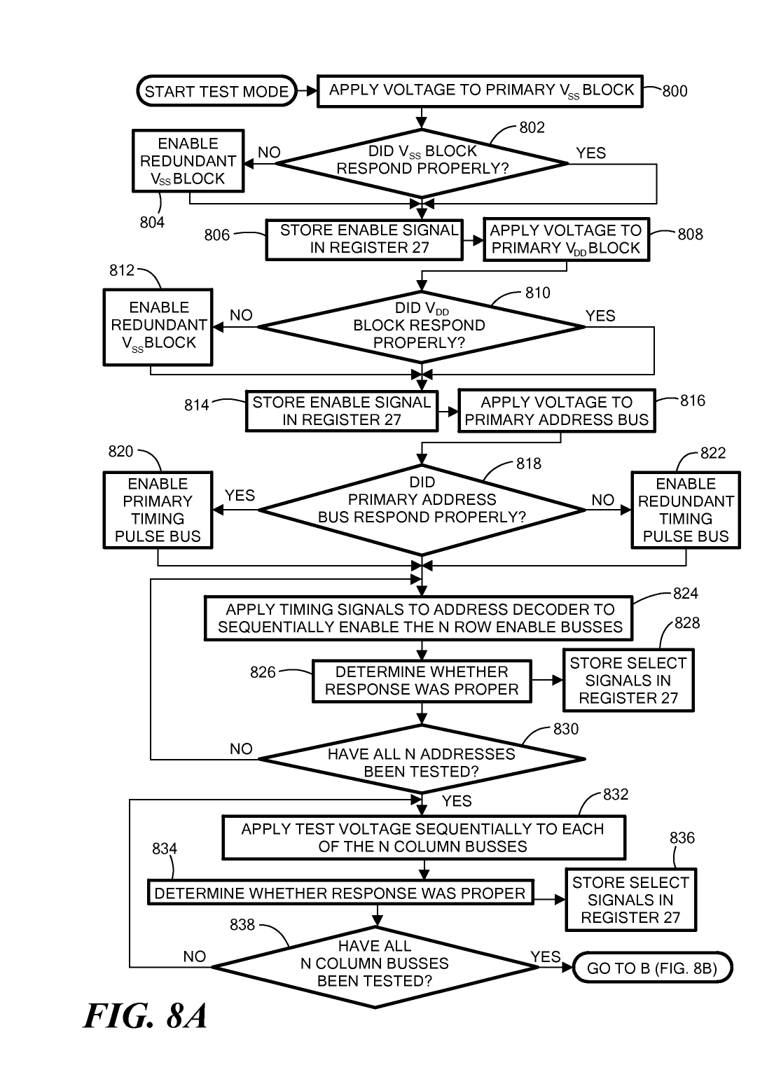

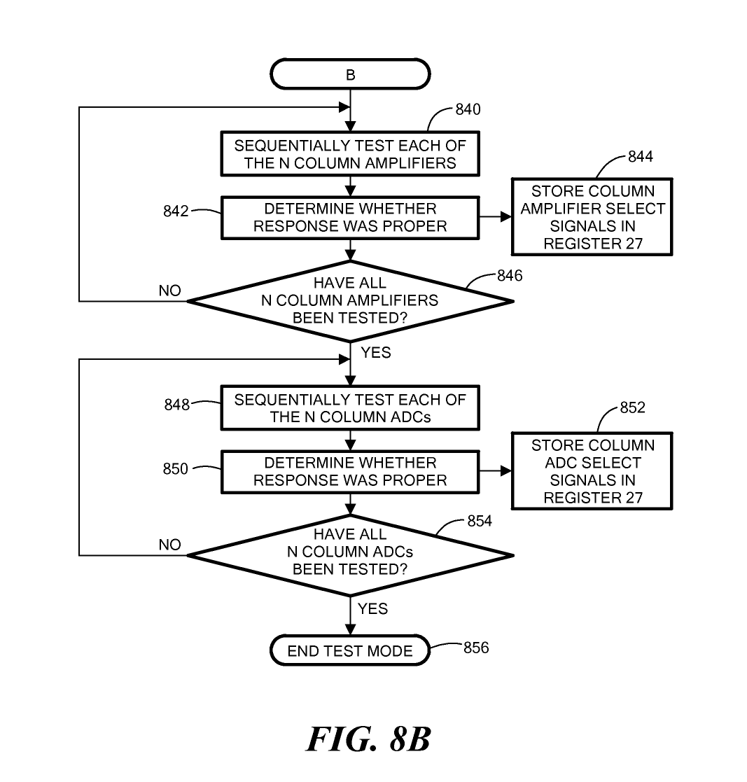

Referring now to FIGS. 8, 8A and 8B a flowchart is shown of a process used by the focal plane array (FPA) processor 23 in managing defects in focal plane arrays using redundant components. Apply voltage to primary Vₛₛ block (Step 800). Did Vₛₛ block respond properly (Step 802)? If yes, store enable signal in register 27. If not, enable redundant Vₛₛ block (step 804) and store enable signal in register 27 (Step 806). Apply voltage to primary V_{dd} block (Step 808). Did V_{dd} block respond properly (Step 810)? If yes, store enable signal in register 27 (Step 814); if not, enable redundant Vₛₛ block (Step 812) and store enable signal in register 27 (Step 814). Apply voltage to primary address bus (Step 816). Did primary address buss respond properly (Step 818)? If yes, enable primary timing pulse bus (Step 820); if not, enable redundant timing pulse bus (Step 822). Apply timing signals to address decoder to sequentially enable the N row enable busses 824). Determine whether response was proper (Step 826). Store select signal in register 27 (Sep 828). Have all N address rows been enabled (Step 830)? If not, return to apply timing signals to address decoder to sequentially enable the N row enable busses (Step 824); if yes, apply test voltage sequentially to each of the N column busses (Step 832). Determine whether response was proper (Sep 834). Store select signals in register 27 (Step 836). Have all N column busses been tested (Step 838)? If not, return to apply test voltage sequentially to each of the N column busses (Sep 832). If yes, sequentially test each of the N column amplifiers (Step 840). Determine whether response was proper (Step 842). Store column amplifier select signals in register 27 (Step 844). Have all N column amplifiers been tested (Step 846)? If not, return to sequentially test each of the N column amplifiers (Step 840); if yes, sequentially test each of the N column ADCs (Step 848). Determine whether response was proper (Step 850). Store column ADC select signals in register 27 (Step 852). Have all N column ADCs been tested (Step 854)? If not, return to sequentially test each of the N column ADCs (Step 848). If yes, end test mode (Step 856).

A number of embodiments of the disclosure have been described. Nevertheless, it will be understood that various modifications may be made without departing from the spirit and scope of the disclosure. For example, the test section may be arranged to enable the primary ROIC section to operate with the redundant ROIC section disabled during an initial power up phase and to test the primary ROTC circuit section during the initial power up phase to detect a fault that might prevent the primary ROIC from powering up and, upon detection of the fault, decoupling the detected electronic circuit element from the array and the redundant ROIC section to be coupled to the array. Accordingly, other embodiments are within the scope of the following claims.

What is claimed is:

1. A focal plane array, comprising:
an imaging array section, comprising:
an array of electromagnetic radiation detectors; and
an address decoder for providing outputs from selectively enabled detectors; and
wherein the imaging array section comprises a plurality of circuit blocks, each one of the circuit blocks having a primary circuit and a redundant circuit;
test circuitry, for providing test signals to sequentially test each one of the primary circuits and determining whether a response from the test signal provided to the tested primary circuit is proper or improper and for storing in the test circuitry in response to such determining a select signal associated with each one of the tested circuit blocks;
an array controller for, during a subsequent normal operating mode, provides timing pulses to the address decoder for selectively enabling the detectors using either the primary or redundant circuits in each one of the plurality of circuit blocks selectively in accordance with the stored select signal associated with such one of the circuit blocks.

2. The focal plane array recited in claim 1 wherein one of the circuit blocks is a Timing Signal circuit block.

3. The focal plane array recited in claim 1 wherein one of the circuit blocks is an Address Decoder Section Block.

4. The focal plane array recited in claim 1 wherein one of the circuit blocks is Row Address Enable Block.

5. The focal plane array recited in claim 1 wherein one of the circuit Mocks is an Imaging Array Column Output Section.

6. The focal plane array recited in claim 1 wherein one of the circuit blocks is an Imaging Array Column Output Section includes a plurality of column output sections.

7. A focal plane array, comprising:
a first semiconductor wafer having formed therein an array of electromagnetic radiation detectors;
a semiconductor structure, connected to the array of detectors, having:
an imaging array section comprises a plurality of circuit blocks, each one of the circuit blocks having a primary circuit and a redundant circuit; and
a processor, the processor comprising:
a test module; and
a storage element; and
wherein:
during a test mode, the test module operates to test the primary circuit of each one of the plurality of circuit blocks and determine whether a response is proper or improper from the test and for storing in the storage element in response to such determining a select signal associated with each one of the tested circuit blocks; and
during a subsequent normal operating mode, the processor provides timing pulses to the imaging array section for selectively responding to radiation sensed by the detectors using either the primary or redundant circuit in each one of the plurality of circuit blocks selectively in accordance with the stored select signal associated with such one of the circuit blocks.

8. A semiconductor structure, comprising:
a first semiconductor having formed thereon an array of electromagnetic radiation detectors;
a semiconductor structure electrically connected to the first semiconductor substrate, the second semiconductor substrate having formed thereon:
primary and redundant circuits each comprising a plurality of circuit blocks arranged for controlling readout of packets of charge stored wells of the detectors and for converting the readout stored packets into corresponding voltages and for converting such voltages into corresponding digital signals; and
a test section for, upon detection of a fault in the primary circuit section, or in one of the primary circuit blocks, decoupling the primary circuit, or fault detected, circuit block, from the array and replacing the primary circuit, or the fault detected circuit block, with the redundant circuit, or with a corresponding one of the circuit blocks, in the redundant circuit.

9. The focal plane array recited in claim 1 wherein the test section tests for proper logic operation of the circuit blocks of the primary section,

10. The focal plane array recited in claim 1 wherein the test section tests for signal integrity in the circuit blocks of the primary section.

11. The focal plane array recited in claim 1 wherein the test section tests for signal integrity in the row and column addressing blocks of the primary section.

12. The focal plane array recited in claim 1 wherein the test section tests for signal integrity in circuitry for converting the voltages into corresponding digital signals;
